(19) United States
(12) Patent Application Publication
(10) Pub. No.: US 2026/0076113 A1
(43) Pub. Date: Mar. 12, 2026

(54) SYSTEMS AND METHODS FOR STRESS REDUCTION IN POROUS LAYERS

(71) Applicant: IQE plc, St. Mellons, Cardiff (GB)

(72) Inventor: Richard HAMMOND, St. Mellons, Cardiff (GB)

(21) Appl. No.: 19/136,384

(22) PCT Filed: Dec. 6, 2023
(86) PCT No.: PCT/EP2023/084578

§ 371 Date: Jun. 6, 2025

(30) Foreign Application Priority Data
Dec. 12, 2022 (GB) 2218654.8

(51) Int. Cl. H01L 21/02; H10D 86/00

(52) U.S. Cl. CPC H10P 14/665; H10D 86/201; H10P 14/6309; H10P 14/6519; H10P 14/69215

(57) ABSTRACT

A layered structure can include a porous layer over a substrate and a thermal layer coupled to pore walls of the porous layer. The porous layer can have a higher resistivity than the substrate. A stress of the porous layer can be proportional to a variance of infrared (IR) transmission data of the porous layer. The variance of IR transmission data can be no greater than 2,500. Advantageously the thermal layer can decrease stress in the porous layer, increase thermal stability of the porous layer, decrease cracking and flaking during high temperature processing, maintain high resistivity of the porous layer, and increase the quality of the epitaxial layer and/or semiconductor devices formed using the porous layer.

### BACKGROUND

### Field

The present disclosure relates to porous apparatuses, systems, and methods, for example, porous apparatuses, systems, and methods for forming a thermal layer in a porous layer to reduce stress and increase thermal stability in the porous layer. Reducing stress and increasing thermal stability in the porous layer can enhance the quality of an epitaxial layer grown over the porous layer and/or semiconductor devices formed using the porous layer.

### Background

Semiconductor-on-insulator (SOI) structures are commonly employed to realize radio frequency (RF) designs where low signal leakage is required. These SOI structures use a buried oxide (BOX) under a top device layer in which RF circuit components, such as transistors and/or passive components, can be fabricated. A handle wafer functioning as a substrate under the BOX can result in signal leakage due to RF fringing fields penetrating into the substrate.

Current incumbent RF-SOI technology utilizes a trap-rich SOI to reduce carrier accumulation due to RF fringing fields and reduce harmonic losses. A trap-rich layer (e.g., polysilicon) is formed between the handle wafer and the BOX to minimize parasitic surface conduction effects that can adversely affect RF devices in the top device layer. In addition, to further reduce substrate harmonic losses, high-resistivity handle wafers (e.g., greater than 3,000 Ω·cm) are used to reduce the amount of free charge carriers. However, this approach requires costly and/or specialized fabrication techniques.

Porous semiconductors are an alternative to SOI substrates. Porous semiconductors can achieve high-resistivity properties on a standard CMOS silicon wafer, rather than a high-resistivity SOI wafer. Porosification can form a porous region with a particular thickness and porosity in a layer or substrate. For example, electrochemically etching a standard low-resistivity (e.g., 1 Ω·cm) silicon wafer can form a thick (e.g., greater than 10 microns) porous silicon surface layer. The porous etch can deplete free charge carriers within the silicon and increase a resistivity of the porous silicon layer by several orders of magnitude (e.g., from 1 Ω·cm to greater than 5,000 Ω·cm). The high-resistivity and low relative permittivity (e.g., about 2.2) of porous silicon can suppress harmonic losses by several orders of magnitude more than trap-rich SOI.

Further, porous silicon provides an epitaxy platform to regrow a defect-free, single crystal silicon epilayer. Epitaxy refers to crystal growth or material deposition in which new crystalline layers are formed with one or more well-defined orientations. Epitaxy can be used to grow high quality, single crystal semiconductors atop the porous layer. For example, such an epilayer can be used as a device layer for RF circuit components (e.g., an RF CMOS switch).

However, when a thick porous layer undergoes high temperature processing (e.g., greater than 400° C.), cracking and flaking in the porous layer can occur. High temperature processing can induce stress within the porous layer, contributing to structural defects. Further, atoms in the porous layer can migrate and reorganize during high temperature processing causing thermal instability in the porous layer. In addition, stress and/or cracking in the porous layer can cause accompanying defects in quality and uniformity of an epitaxial layer grown over the porous layer.

### SUMMARY

Accordingly, there is a need to utilize a thermal layer coupled to pore walls in a porous layer to simultaneously decrease stress in the porous layer, increase thermal stability of the porous layer, decrease cracking and flaking during high temperature processing, maintain high resistivity of the porous layer (e.g., greater than 5,000 Ω·cm), and increase quality and uniformity of an epitaxial layer grown directly over the porous layer (e.g., decreased dislocation density).

In some aspects, a layered structure can include a porous layer over a substrate and a thermal layer coupled to pore walls of the porous layer. In some aspects, the porous layer can have a higher resistivity than the substrate. In some aspects, a stress of the porous layer can be proportional to a variance of infrared (IR) transmission data for the porous layer. In some aspects, the variance of the IR transmission data can be no greater than 2,500. Advantageously the thermal layer can reduce stress (proportional to the IR transmission data) within the porous layer, increase thermal stability of the porous layer, and reduce atom migration during high temperature processing, thereby reducing defects (e.g., cracking, flaking, etc.) in the porous layer. Further advantageously the thermal layer can maintain a high resistivity of the porous layer.

In some aspects, the variance of IR transmission data can be no greater than 1,000. In some aspects, the variance of IR transmission data can be no greater than 500. Advantageously reduced stress (proportional to the IR transmission data) in the porous layer can increase the stability of the porous layer during any high-temperature processing and increase the quality and uniformity of the epitaxial layer.

In some aspects, the layered structure can further include an epitaxial layer grown directly over the porous layer. In some aspects, a dislocation density of the epitaxial layer can be approximately equivalent to that of bulk silicon. Advantageously increasing the quality of the epitaxial layer can increase the performance of semiconductor devices fabricated within the epitaxial layer and increase yield.

In some aspects, the porous layer can have a thickness of at least 2 μm. In some aspects, the porous layer can have a thickness of at least 10 μm. Advantageously a thick porous layer with a high resistivity can reduce harmonic losses and increase performance of fabricated semiconductor devices (e.g., RF device).

In some aspects, the thermal layer can be configured to decrease migration of atoms in the porous layer thereby increasing thermal stability of the porous layer at temperatures greater than about 850° C. Advantageously increasing thermal stability can reduce cracking and flaking of the porous layer during high temperature processing.

In some aspects, the thermal layer can extend continuously along the pore walls from a frontside of the porous layer to a backside of the porous layer. Advantageously a continuous thermal layer can decrease stress and increase thermal stability within the porous layer at high temperatures.

In some aspects, the thermal layer can partially fill the space between the pore walls. Advantageously a partially filled thermal layer can reduce stress and increase thermal stability within the porous layer at high temperatures.

In some aspects, the thermal layer can completely fill the space between the pore walls. Advantageously a completely filled porous layer can reduce stress and increase thermal stability within the porous layer at high temperatures.

In some aspects, the thermal layer can include silicon dioxide (SiO₂). Advantageously a thermal layer including SiO₂ can reduce stress within the porous layer, increase thermal stability of the porous layer at high temperatures, and maintain a high resistivity of the porous layer.

In some aspects, the layered structure can further include a semiconductor device in the porous layer. In some aspects, the semiconductor device in the porous layer can include a radio frequency (RF) device. In some aspects, the semiconductor device in the porous layer can include a passive device (e.g., an inductor, a filter, etc.). Advantageously the thermal layer can reduce stress in the porous layer, thereby reducing instability and increasing the quality of the porous layer when a semiconductor device is formed in the porous layer. Advantageously increasing the quality of the porous layer can increase the performance of semiconductor devices fabricated in the porous layer.

In some aspects, the layered structure can further include an epitaxial layer grown directly over the porous layer. In some aspects, the layered structure can further include a semiconductor device in the epitaxial layer. In some aspects, the semiconductor device in the epitaxial layer can include a radio frequency (RF) device. In some aspects, the semiconductor device in the epitaxial layer can include a passive device (e.g., an inductor, a filter, etc.). In some aspects, the semiconductor device can include a transistor of a radio frequency (RF) switch. Advantageously the thermal layer can reduce stress in the porous layer, thereby reducing a dislocation density of the epitaxial layer. Advantageously increasing the quality of the epitaxial layer can increase the performance of semiconductor devices fabricated in the epitaxial layer.

In some aspects, a method can include forming a porous layer over a substrate. In some aspects, the method can further include heating the porous layer in an oxidizing environment to form a thermal layer coupled to pore walls of the porous layer. In some aspects, a ratio (° C./hr) of a heating temperature and a heating time of the porous layer can be between a range of about 10° C./hr to about 500° C./hr. In some aspects, the method can further include growing an epitaxial layer or forming a semiconductor device directly over the porous layer. In some aspects, growing the epitaxial layer or forming the semiconductor device can be after heating the porous layer. Advantageously the method can reduce stress within the porous layer, increase thermal stability of the porous layer, and reduce atom migration during high temperature processing, thereby reducing defects (e.g., cracking, flaking, etc.) in the porous layer. Further advantageously the thermal layer can maintain a high resistivity of the porous layer.

In some aspects, the range of the ratio can be configured to reduce stress within the porous layer and decrease a dislocation density of the epitaxial layer. Advantageously increasing the quality of the epitaxial layer by decreasing stress in the porous layer can increase the performance of semiconductor devices fabricated in the epitaxial layer and increase yield.

In an aspect, the heating temperature can be about 75° C. to about 500° C. In an aspect, the heating temperature can be at least 200° C. In an aspect, the heating temperature can be at least 300° C. Advantageously the heating temperature can contribute to thermal oxidation of the pore walls of the porous layer, thereby forming the thermal layer. Further advantageously the heating temperature can reduce stress in the porous layer (e.g., relaxing the porous lattice structure).

In an aspect, the heating time is about 30 minutes to about 5 hours. In an aspect, the heating time is no longer than 3 hours. In an aspect, the heating time is no longer than 1 hour. Advantageously the heating time can contribute to thermal oxidation of the pore walls of the porous layer, thereby forming the thermal layer. Further advantageously the heating temperature and heating time can be adjusted based on parameters of the porous layer (e.g., thickness, porosity, material, etc.) to control (e.g., decrease) the amount of stress in the porous layer.

In some aspects, the oxidizing environment can include air, oxygen, steam, or a combination thereof. Advantageously the oxidizing environment can contribute to thermal oxidation of the pore walls of the porous layer, thereby forming the thermal layer.

In some aspects, the method can further include preparing the pore walls of the porous layer for passivation prior to heating the porous layer. In some aspects, preparing the pore walls of the porous layer for passivation can include hydrogen terminating dangling bonds within the pore walls. Advantageously preparing the pore walls of the porous layer for passivation prior to heating the porous layer can increase the quality and uniformity of the thermal layer, reducing stress.

In some aspects, heating the porous layer can include annealing the porous layer. Advantageously annealing can decrease stress in the porous layer and increase thermal stability (e.g., crystallinity) of the porous layer prior to growth of the epitaxial layer over the porous layer.

Implementations of any of the techniques described above can include a system, a method, a process, a device, and/or an apparatus. The details of one or more implementations are set forth in the accompanying drawings and the description below. Other features will be apparent from the description and drawings, and from the claims.

Further features and exemplary aspects of the aspects, as well as the structure and operation of various aspects, are described in detail below with reference to the accompanying drawings. It is noted that the aspects are not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the aspects and, together with the description, further serve to explain the principles of the aspects and to enable a person skilled in the relevant art(s) to make and use the aspects.

FIG. 1 is a schematic cross-sectional illustration of a previously known trap-rich SOI layered structure.

FIG. 2 is a schematic cross-sectional illustration of a porosification system, according to an exemplary aspect.

FIG. 3A is a schematic cross-sectional illustration of a porous layered structure, according to an exemplary aspect.

FIG. 3B is a schematic cross-sectional illustration of a porous layered structure, according to an exemplary aspect.

FIG. 4 is a schematic circuit diagram of a transceiver including an RF switch employing stacked transistors, according to an exemplary aspect.

FIG. 5 is a schematic cross-sectional illustration of a porous layered structure prior to high temperature processing, according to an exemplary aspect.

FIG. 6 is a schematic cross-sectional illustration of the porous layered structure shown in FIG. 5 after growth of an epitaxial layer and high temperature processing, according to an exemplary aspect.

FIG. 7 is a schematic cross-sectional illustration of the porous layer of the porous layered structure shown in FIG. 3A, according to an exemplary aspect.

FIG. 8 is a schematic cross-sectional illustration of a porous layer with a thermal layer partially filling the pore walls, according to an exemplary aspect.

FIG. 9 is a schematic cross-sectional illustration of a porous layer with a thermal layer completely filling the pore walls, according to an exemplary aspect.

FIG. 10 is an infrared (IR) transmission image of a porous layer prior to heating, according to an exemplary aspect.

FIG. 11 is an IR transmission image of a porous layer after heating in an oxidizing environment, according to an exemplary aspect.

FIG. 12 is an IR transmission image of a porous layer prior to heating, according to an exemplary aspect.

FIG. 13 is an IR transmission image of a porous layer after heating in a non-oxidizing environment, according to an exemplary aspect.

FIG. 14 is a schematic manufacturing diagram for forming a porous layered structure with a thermal layer, according to an exemplary aspect.

FIGS. 15-18 are IR transmission images of porous layers after heating in an oxidizing environment and after growing an epitaxial layer over the porous layers, according to exemplary aspects.

FIG. 19 is a flow diagram for forming the porous layered structure shown in FIG. 14, according to an exemplary aspect.

The features and exemplary aspects of the aspects will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more aspects that incorporate the features of this present invention. The disclosed aspect(s) merely exemplify the present invention. The scope of the invention is not limited to the disclosed aspect(s). The present invention is defined by the claims appended hereto.

The aspect(s) described, and references in the specification to “one aspect,” “an aspect,” “an example aspect,” “an exemplary aspect,” etc., indicate that the aspect(s) described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to affect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The term “about” or “substantially” or “approximately” as used herein means the value of a given quantity that can vary based on a particular technology. Based on the particular technology, the term “about” or “substantially” or “approximately” can indicate a value of a given quantity that varies within, for example, 0.1-10% of the value (e.g., ±0.1%, ±1%, ±2%, ±5%, or ±10% of the value).

The term “epitaxy” or “epitaxial” as used herein means crystalline growth of material, for example, via high temperature deposition. Epitaxy can be effected in a molecular beam epitaxy (MBE) tool in which layers are grown on a heated substrate in an ultra-high vacuum environment. Elemental sources are heated in furnaces and directed towards the substrate without carrier gases. The elemental constituents react at the substrate surface to create a deposited layer.

Epitaxy can also be performed in a vapor phase epitaxy (VPE) tool, also known as a chemical vapor deposition (CVD) tool. CVD is the formation of stable solids by decomposition of gaseous chemicals using heat, plasma, ultraviolet, or other energy sources. Silicon epitaxy can be produced by CVD using heat as the energy source to decompose gaseous chemicals. For example, silicon and dopant atoms can be brought to a single crystal surface by gaseous transport to form a doped epitaxial layer. The CVD tool can be controlled by reactor design variables and operator variables, each of which can influence the uniformity, productivity, and quality of the epitaxial layer.

Epitaxy can also be performed in a metal-organic vapor phase epitaxy (MOVPE) tool, also known as a metal-organic chemical vapor deposition (MOCVD) tool. Compound metal-organic and hydride sources flow over a heated surface using a carrier gas, for example, hydrogen. Epitaxial deposition in the MOCVD tool occurs at higher pressures than in an MBE tool. The compound constituents are cracked in the gas phase and then reacted at the surface to grow layers of desired composition.

The term “compound semiconductor material” or “Group III-V semiconductor” or “III-V semiconductor” or “III-V material” as used herein means including one or more materials from Group III of the periodic table (e.g., group 13 elements: boron (B), aluminum (Al), gallium (Ga), indium (In), thallium (Tl)) with one or more materials from Group V of the periodic table (e.g., group 15 elements: nitrogen (N), phosphorus (P), arsenic (As), antimony (Sb), bismuth (Bi)). The compounds have a 1:1 combination of Group III and Group V regardless of the number of elements from each group. Subscripts in chemical symbols of compounds refer to the proportion of that element within that group. For example, Al_{0.25}Ga_{0.75}As means the Group III part comprises 25% Al, and thus 75% Ga, while the Group V part comprises 100% As.

The term “Group IV semiconductor” as used herein indicates comprising one or more materials from Group IV of the periodic table (e.g., group 14 elements: carbon (C), silicon (Si), germanium (Ge), tin (Sn), lead (Pb)). An alloy can be formed from one or more Group IV elements. Subscripts in chemical symbols of the alloy refer to the proportion of that element within the alloy. For example, Si_{0.8}Ge_{0.2} means the alloy comprises 80% Si and 20% Ge.

The term “Group II-VI semiconductor” as used herein indicates comprising one or more materials from Group II of the periodic table (e.g., group 12 elements: zinc (Zn), cadmium (Cd), mercury (Hg)) with one or more materials from Group VI of the periodic table (e.g., group 16 elements: oxygen (O), sulfur (S), selenium (Se), tellurium (Te)).

The term “substrate” as used herein means a planar wafer on which subsequent layers may be deposited, formed, or grown. A substrate may be formed of a single element (e.g., Si) or a compound material (e.g., GaAs), and may be doped or undoped. In some aspects, for example, a substrate can include Si, Ge, GaAs, GaN, GaP, GaSb, InP, InSb, a Group IV semiconductor, a Group III-V semiconductor, a Group II-VI semiconductor, graphene, or silicon carbide (SiC).

A substrate may be on-axis, that is where the growth surface aligns with a crystal plane. For example, a substrate can have <100> crystal orientation. Reference herein to a substrate in a given crystal orientation also encompass a substrate which is miscut by up to about 20° towards another crystallographic direction. For example, a (100) substrate miscut towards the (111) plane.

The term “monolithic” as used herein means a layer or substrate comprising bulk (e.g., single) material throughout. Alternatively, the layer or substrate may be porous for some or all of its thickness.

The term “doping” or “doped” as used herein means that a layer or material contains a small impurity concentration of another element (dopant) which donates (donor) or extracts (acceptor) charge carriers from the parent material and therefore alters the conductivity. Charge carriers may be electrons or holes. A doped material with extra electrons is called n-type while a doped material with extra holes (fewer electrons) is called p-type.

The term “crystalline” as used herein means a material or layer with a single crystal orientation. In epitaxial growth or deposition, subsequent layers with the same or similar lattice constant follow the registry of the previous crystalline layer and therefore grow with the same crystal orientation or crystallinity. As will be understood by a person of ordinary skill in the art, crystal orientation, for example, <100> means the face of cubic crystal structure and encompasses [100], [010], and [001] orientations using the Miller indices. Similarly, for example, <0001> encompasses [0001] and [000-1], except if the material polarity is critical. Also, integer multiples of any one or more of the indices are equivalent to the unitary version of the index. For example, (222) is equivalent to (111).

The term “lattice matched” as used herein means that two crystalline layers have the same, or similar, lattice spacing such that the second layer will tend to grow isomorphically (e.g., same crystalline form) on the first layer, also known as pseudomorphic (e.g., near-lattice-matched).

The term “lattice constant” as used herein means the smallest periodicity of a crystalline lattice along a certain crystal orientation. For example, the unstrained lattice spacing of a crystalline unit cell.

The term “deposition” as used herein means the depositing of a layer on another layer or substrate. Deposition encompasses epitaxy, physical vapor deposition (PVD), electron-beam PVD (EBPVD), sputter deposition, chemical vapor deposition (CVD), plasma-enhanced CVD (PECVD), atomic layer deposition (ALD), powder bed deposition, and/or other known techniques to deposit material in a layer.

The term “lateral” or “in-plane” as used herein means parallel to the surface of the substrate and perpendicular to the growth direction.

The term “vertical” or “out-of-plane” as used herein means perpendicular to the surface of the substrate and in the growth direction.

The term “porosifying” or “porosification” as used herein means forming a porous region with a particular thickness and porosity in a layer or substrate. The porosity of a material is affected by electrolyte concentration, electrolyte current density, electrolyte current fluid velocity, anodization time, temperature, and/or material doping. Porosifying can include electrochemical (EC) etching or photoelectrochemical (PEC) etching to form one or more porous layers in a layer or substrate. For example, an electrolyte current (e.g., hydrofluoric acid (HF) at 100 mA/cm² and 20° C.) can be applied to a layer to form one or more porous layers.

The term “porous region” or “porous layer” as used herein means a layer that includes air or vacuum pores, with the porosity defined as the proportion of the area which is occupied by the pores rather than the bulk (e.g., single) material (e.g., a percentage %). The porosity can vary through the thickness of the layer. For example, the layer may be porous in one or more sublayers. The layer may include an upper portion which is porous and a lower portion that is non-porous. The porosity may be constant or variable within the porous region. Where the porosity is variable, the porosity may be linearly varied through the thickness, or may be varied according to a different function, for example, quadratic, logarithmic, or a step function. Pores in the porous layer can be microporous (e.g., less than 2 nm pore size), mesoporous (e.g., 2 nm to 50 nm pore size), nanoporous (e.g., less than 100 nm pore size), or macroporous (e.g., 50 nm to 1000 nm pore size).

Numerical values, including endpoints of ranges, can be expressed herein as approximations preceded by the term “about,” “substantially,” “approximately,” or the like. In such cases, other aspects include the particular numerical values. Regardless of whether a numerical value is expressed as an approximation, two aspects are included in this disclosure: one expressed as an approximation, and another not expressed as an approximation. It will be further understood that an endpoint of each range is significant both in relation to another endpoint, and independently of another endpoint.

Before describing aspects of the present disclosure in more detail, it is instructive to present exemplary layered structures, porosification systems, and environments in which aspects of the present disclosure may be implemented.

### Exemplary Layered Structures and Porosification Systems

As discussed above, porous semiconductors are an alternative to current incumbent RF-SOI technology that utilize trap-rich SOI substrates. Porosification can form a thick porous region with a particular thickness (e.g., greater than 10 microns) and porosity (e.g., about 35% to 65%) in a layer or substrate, and achieve high-resistivity (e.g., greater than 5,000 Ω·cm) on a standard CMOS wafer (e.g., silicon wafer). The high-resistivity porous layer (e.g., porous silicon) can suppress harmonic losses by several orders of magnitude more than trap-rich SOI. Further, the porous layer provides an epitaxy platform to regrow a defect-free, single crystal epilayer. For example, such an epilayer can be used as a device layer for RF circuit components (e.g., an RF CMOS switch).

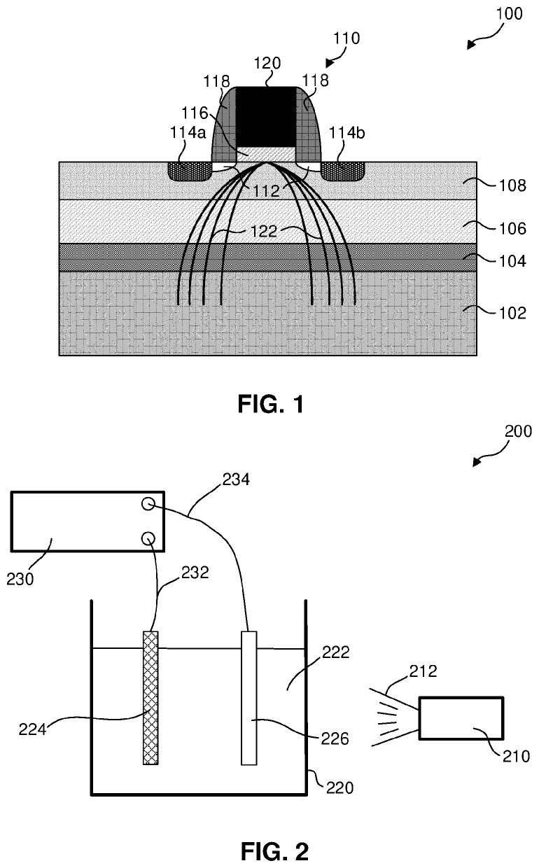

FIG. 1 illustrates trap-rich SOI layered structure 100, according to a previously known configuration. In the example shown in FIG. 1, trap-rich SOI layered structure 100 includes substrate 102 (e.g., silicon), trap-rich layer 104 (e.g., polysilicon), buried oxide (BOX) layer 106 (e.g., silicon dioxide), semiconductor layer 108 (e.g., silicon), and semiconductor device 110 (e.g., MOSFET) in semiconductor layer 108. According to such a configuration, semiconductor device 110 produces RF field lines 122 that penetrate (bleed) through trap-rich layer 104 and BOX layer 106 into substrate 102. This configuration causes significant harmonic losses, crosstalk, and parasitic surface conduction effects.

Semiconductor device 110 can include lightly doped regions 112, source/drain junctions 114a, 114b, gate oxide 116, spacers 118, and gate 120. Lightly doped regions 112 can be implanted with a dopant of a different type (e.g., n-type) than the corresponding semiconductor layer 108 (e.g., p-type). Source/drain junctions 114a, 114b can be implanted with a dopant of the same type as adjacent lightly doped regions 112, but having a higher concentration than lightly doped regions 112. Gate oxide 116 can comprise an electrical insulator, for example, silicon dioxide (SiO₂). Spacers 118 can comprise an electrical insulator, for example, silicon nitride (SiN). Gate 120 can comprise an electrical conductor, for example, polysilicon.

FIG. 2 illustrates porosification system 200, according to an exemplary aspect. Porosification system 200 can be configured to form one or more porous layers in a layer or substrate. In some aspects, porosification system 200 can utilize electrochemical (EC) etching, photoelectrochemical (PEC) etching, or a combination thereof to form one or more porous layers. Although porosification system 200 is shown in FIG. 2 as a stand-alone apparatus and/or system, aspects of this disclosure can be used with other apparatuses, systems, and/or methods.

As shown in FIG. 2, porosification system 200 can include illumination source 210, bath 220, and current source 230. In some aspects, a portion of a layer or substrate (e.g., in-plane or out-of-plane) can be exposed to an electrolyte current such that the portion is etched and a porous region remains. In some aspects, a porosity of the porous region can be controlled by adjusting electrolyte concentration, electrolyte current density, electrolyte current fluid velocity, porosification time, temperature, material doping, illumination power, and/or illumination wavelength. In some aspects, a thickness of the porous region can be controlled by adjusting a porosification (etching) time.

Illumination source 210 is configured to supplement EC etching of a layer or substrate (e.g., substrate 226) in bath 220 with PEC etching to form a porous region in the layer or substrate. PEC etching is dopant and bandgap selective and creates holes at the surface of the layer or substrate. Illumination source 210 can include a UV source (e.g., mercury lamp, arc lamp, etc.) and generate PEC illumination 212 over a portion or all of the layer or substrate. In some aspects, illumination source 210 can be a pulsed light source or include a mechanical modulator (e.g., chopper), an acousto-optical modulator (AOM), or an electro-optical modulator (EOM) to generate pulsed illumination having a particular frequency. In some aspects, illumination source 210 can have a power of about 1 mW to 10 W. In some aspects, illumination source 210 can include an optical filter to apply a particular wavelength(s) to the layer or substrate. In some aspects, illumination source 210 can be omitted for pure EC etching.

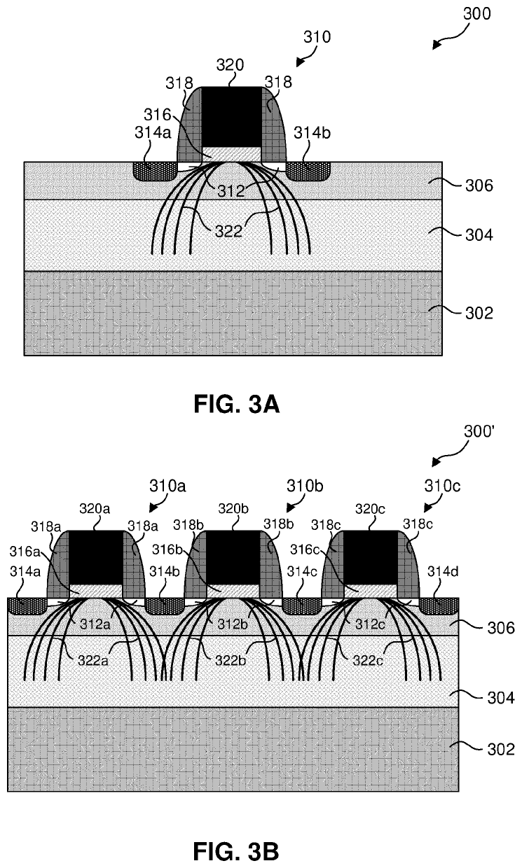

Bath 220 is configured to provide EC etching (e.g., chemical etch) of a layer or substrate (e.g., substrate 226) to form a porous region in the layer or substrate. Bath 220 can include electrolyte 222, electrode 224, and substrate 226 (e.g., substrate 302 shown in FIGS. 3A and 3B). In some aspects, electrolyte 222 can include any material (e.g., acid, alkali, oxidizer, salt, etc.) to facilitate EC etching of substrate 226. For example, electrolyte 222 can include hydrofluoric (HF) acid, buffered HF (5:2), hydrochloric (HCl) acid, hydrobromic (HBr) acid, sulfuric acid (H₂SO₄), nitric acid (HNO₃), oxalic acid (C₂H₂O₄), sodium hydroxide (NaOH), potassium hydroxide (KOH), hydrogen peroxide (H₂O₂), or any other suitable acid, alkali, salt, or oxidizer. Electrode 224 can include any suitable conductor (e.g., metal, copper (Cu), aluminum (Al), platinum (Pt), etc.). In some aspects, bath 220 can maintain a temperature of about 20° C. to about 60° C. In some aspects, substrate 226 can include substrate 302 or a portion (e.g., upper surface) of substrate 302 shown in FIGS. 3A and 3B. In some aspects, substrate 226 can be coupled to a holder such that one side of substrate 226 (e.g., frontside) is exposed to electrolyte 222 during EC etching while the opposite side of the substrate 226 (e.g., backside) is sealed and not exposed to electrolyte 222 during EC etching.

Current source 230 is configured to provide EC etching (e.g., current etch) of a layer or substrate (e.g., substrate 226) to form a porous region in the layer or substrate. Current source 230 can include cathode 232 and anode 234. When combined, current source 230 and bath 220 form an electrolyte current. In some aspects, as shown in FIG. 2, cathode 232 can be connected to electrode 224 and anode 234 can be connected to substrate 226 to complete the circuit. When current is applied, substrate 226 is etched (e.g., porosified), with or without illumination source 210, and electron flow is away from substrate 226 towards electrode 224. Electrons resonate at pore tips in substrate 226 and porosity extends through substrate 226. In some aspects, the electrolyte current density is about 1 mA/cm2 to about 350 mA/cm2. For example, the electrolyte current density can be about 10 mA/cm2 to about 100 mA/cm2. In some aspects, the lattice parameter of the starting material (e.g., substrate 226) remains relatively unchanged following the porosification process. In some aspects, a porosification rate in substrate 226 can be about 1 nm/min to about 25 μm/min. For example, the porosification rate can be about 0.1 μm/min to about 5 μm/min.

In some aspects, porosification system 200 can perform a porosification process (e.g., EC etch) on substrate 226 by exposing a portion of substrate 226 (e.g., frontside) to electrolyte 222 (e.g., buffered HF) and applying (passing) an electrolyzing current (e.g., in a range of 5 mA/cm² to 100 mA/cm²) through substrate 226 from cathode 232 and anode 234 for a specified time (e.g., for 10 seconds to 15 minutes). In some aspects, the porosification process can be carried out in a constant voltage mode (e.g., DC bias of about 5 V to about 25 V) and controlled by monitoring an etching current signal. In some aspects, the porosification process can be carried out in a constant current mode (e.g., DC current density of about 5 mA/cm² to about 100 mA/cm²) and controlled by monitoring an etching current signal. In some aspects, the porosification process can include oxidation of substrate 226 by localized injection of holes upon application of a positive anodic bias (e.g., anode 234), and localized dissolution of such oxide layer in electrolyte 222 resulting in a porous layer (e.g., porous layer 304 shown in FIGS. 3A and 3B). In some aspects, the porosification process ends when the etching current signal drops to a base line level, indicating that all of the exposed portions of substrate 226 have been porosified and converted into a porous layer (e.g., porous layer 304 shown in FIGS. 3A and 3B).

In some aspects, substrate 226 can comprise any suitable substrate having a predetermined crystallographic orientation, including but not limited to silicon, germanium, and III-V semiconductors. In some aspects, substrate 226 can be doped prior to porosification to adjust a resistivity of substrate 226, for example, to a low-resistivity in a range of about 0.1 Ω·cm to 10 Ω·cm. In some aspects, electrolyte 222 can include a mixture of HF and deionized water, for example, having a ratio of (5:2) and surfactant (1 ml/l). In some aspects, electrolyte 222 can include a mixture of HF and an alcohol (e.g., ethanol), for example, having a ratio of (5:2).

In some aspects, porosification system 200 can form a porous layer (e.g., porous layer 304 shown in FIGS. 3A and 3B) that provides an epitaxy platform for subsequent regrowth of a defect-free, single crystal epilayer (e.g., epilayer 306 shown in FIGS. 3A and 3B). For example, porosification system 200 can form a porous layer (e.g., porous layer 304 shown in FIGS. 3A and 3B) with a low porosity (e.g., about 35%) such that the porous layer is relatively crystalline and long-range crystallinity of the porous layer is not significantly affected by the porosification process.

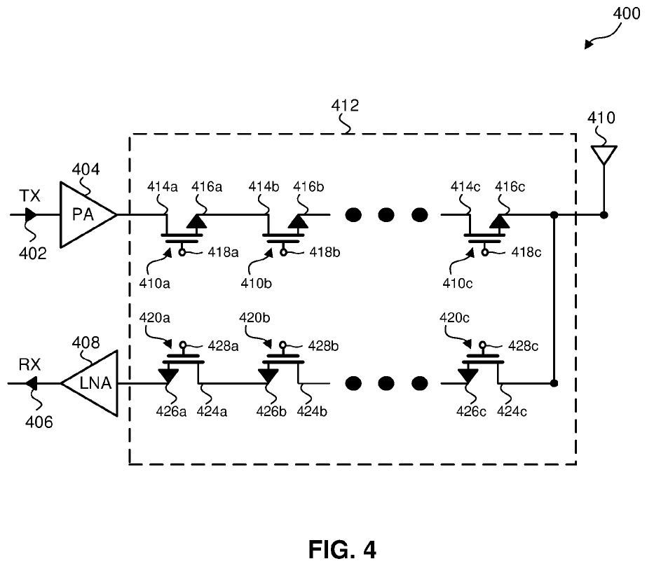

FIGS. 3A and 3B illustrate porous layered structures 300, 300′, according to exemplary aspects. Porous layered structures 300, 300′ can be configured to reduce signal leakage and suppress RF fringing fields (bleeding). In some aspects, porous layered structures 300, 300′ can be utilized in an RF device, for example, RF switch 412 shown in FIG. 4. Although porous layered structures 300, 300′ are shown in FIGS. 3A and 3B as stand-alone apparatuses and/or systems, aspects of this disclosure can be used with other apparatuses, systems, and/or methods.

As shown in FIG. 3A, porous layered structure 300 can include substrate 302 (e.g., silicon), porous layer 304 (e.g., porous silicon), epilayer 306 (e.g., single crystal silicon epilayer), and semiconductor device 310 (e.g., MOSFET) in epilayer 306. In some aspects, porous layered structure 300 with high-resistivity porous layer 304 (e.g., greater than about 5,000 Ω·cm) can prevent RF field lines 322 from semiconductor device 310 from penetrating (bleeding) into substrate 302. In some aspects, porous layered structure 300 can suppress harmonic losses, reduce crosstalk, and reduce parasitic surface conduction effects.

In some aspects, substrate 302 can comprise any suitable substrate having a predetermined crystallographic orientation, including but not limited to silicon, germanium, and III-V semiconductors. In some aspects, substrate 302 can be doped prior to porosification to adjust a resistivity of substrate 302, for example, to a low-resistivity in a range of about 0.1 Ω·cm to 10 Ω·cm.

In some aspects, porous layer 304 can be a fully depleted porous layer (i.e., free of charge carriers). In some aspects, porous layer 304 can be a porous silicon layer. For example, porous layer 304 can be formed from a silicon substrate. In some aspects, porous layer 304 can have a resistivity greater than about 5,000 Ω·cm. In some aspects, porous layer 304 can have a thickness greater than about 2 microns. In some aspects, porous layer 304 can have a thickness greater than about 10 microns. In some aspects, porous layer 304 can have a porosity of about 35% to 65%. In some aspects, pores in porous layer 304 can be mesoporous (e.g., 2 nm to 50 nm pore size).

In some aspects, epilayer 306 can be a defect-free, single crystal epilayer formed directly atop porous layer 304. In some aspects, epilayer 306 can comprise any suitable epilayer having a predetermined crystallographic orientation, including but not limited to silicon, germanium, and III-V semiconductors. In some aspects, epilayer 306 can have the same crystallographic orientation as substrate 302.

Semiconductor device 310 can include lightly doped regions 312, source/drain junctions 314a, 314b, gate oxide 316, spacers 318, and gate 320. Lightly doped regions 312 can be implanted with a dopant of a different type (e.g., n-type) than the corresponding epilayer 306 (e.g., p-type). Source/drain junctions 314a, 314b can be implanted with a dopant of the same type as adjacent lightly doped regions 312, but having a higher concentration than lightly doped regions 312. Gate oxide 316 can comprise an electrical insulator, for example, SiO₂. Spacers 318 can comprise an electrical insulator, for example, SiN. Gate 320 can comprise an electrical conductor, for example, polysilicon. In some aspects, semiconductor device 310 can be a transistor (e.g., MOSFET) in a CMOS device, for example, an RF switch (e.g., RF switch 412 shown in FIG. 4).

In some aspects the semiconductor device 310 can be formed directly in or on the porous layer 304 and the epilayer 306 be omitted. The semiconductor device 310 is therefore a passive device such as an inductor or filter.

The aspects of porous layered structure 300 shown in FIG. 3A, for example, and the aspects of porous layered structure 300′ shown in FIG. 3B may be similar. Similar reference numbers are used to indicate features of the aspects of porous layered structure 300 shown in FIG. 3A and the similar features of the aspects of porous layered structure 300′ shown in FIG. 3B.

As shown in FIG. 3B, porous layered structure 300′ can include a plurality of semiconductor devices 310a, 310b, 310c in epilayer 306. In some aspects, semiconductor devices 310a, 310b, 310c can be transistors, for example, MOSFETs. In some aspects, as shown in FIG. 3B, source/drain junction 314b can be shared by semiconductor devices 310a, 310b and source/drain junction 314c can be shared by semiconductor devices 310b, 310c. In some aspects, semiconductor devices 310a, 310b, 310c can be utilized in an RF device, for example, RF switch 412 shown in FIG. 4. For example, semiconductor devices 310a, 310b, 310c can generally correspond to transistors 410a, 410b, 410c (or transistors 420a, 420b, 420c) utilized in RF switch 412 shown in FIG. 4.

In some aspects the semiconductor devices 310a, 310b, 310c can be formed directly in or on the porous layer 304 and the epilayer 306 be omitted. The semiconductor devices 310a, 310b, 310c are therefore a passive device such as an inductor or filter.

FIG. 4 illustrates a circuit diagram of a portion of transceiver 400 with RF switch 412, according to an exemplary aspect. RF switch 412 can be configured to switch transceiver 400 between receive and transmit modes. In some aspects, transceiver 400 can be for a wireless communication device. In some aspects, RF switch 412 can be an RF device, for example, a passive RF device (e.g., an RF inductor, an RF filter, etc.). Although transceiver 400 is shown in FIG. 4 as a stand-alone apparatus and/or system, aspects of this disclosure can be used with other apparatuses, systems, and/or methods.

As shown in FIG. 4, transceiver 400 can include transmit input (TX) 402, power amplifier (PA) 404, receive output (RX) 406, low-noise amplifier (LNA) 408, antenna 410, and RF switch 412. RF switch 412 is situated between PA 404 and antenna 410. PA 404 amplifies RF signals transmitted from transmit input 402. The output of PA 404 is coupled to one end of RF switch 412. Another end of RF switch 412 is coupled to antenna 410. Antenna 410 can transmit amplified RF signals. RF switch 412 is also situated between LNA 408 and antenna 410. Antenna 410 also receives RF signals. Antenna 410 is coupled to one end of RF switch 412. Another end of RF switch 412 is coupled to the input of LNA 408. LNA 408 amplifies RF signals received from RF switch 412. Receive output 406 receives amplified RF signals from LNA 408. In some aspects, RF switch 412 can employ stacked transistors.

RF switch 412 can include two stacks of transistors. The first stack includes transistors 410a, 410b, and 410c. Each transistor 410a, 410b, 410c has a corresponding drain 414a, 414b, 414c, source 416a, 416b, 416c, and gate 418a, 418b, 418c. The second stack includes transistors 420a, 420b, and 420c. Each transistor 420a, 420b, 420c has a corresponding drain 424a, 424b, 424c, source 426a, 426b, 426c, and gate 428a, 428b, 428c. When transistors 410a, 410b, and 410c are in OFF states, and transistors 420a, 420b, and 420c are in ON states, transceiver 400 is in receive mode. When transistors 410a, 410b, and 410c are in ON states, and transistors 420a, 420b, and 420c are in OFF states, transceiver 400 is in transmit mode. In some aspects, RF switch 412 can switch transceiver 400 between two transmit modes corresponding to different frequencies, or between two receive modes corresponding to different frequencies. In some aspects, RF switch 412 can be utilized in a semiconductor structure that reduces signal leakage.

### Exemplary Porous Layered Structures

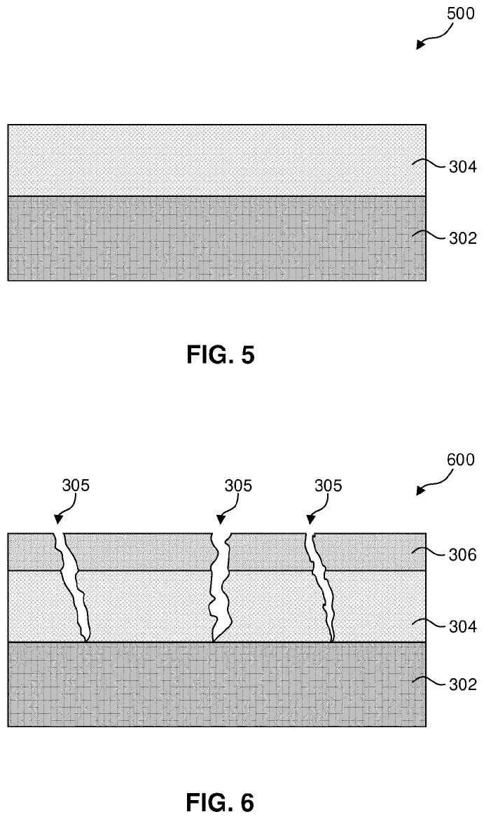

FIG. 5 illustrates porous layered structure 500 prior to high temperature processing, according to an exemplary aspect. As shown in FIG. 5, layered structure 500 can include porous layer 304 over substrate 302. In some aspects, porous layer 304 can have a thickness of at least 2 μm. For example, porous layer 304 can have a thickness of between about 2 μm and about 10 μm. In some aspects, porous layer 304 can have a thickness of at least 10 μm. For example, porous layer 304 can have a thickness of between about 10 μm and about 50 μm.

FIG. 6 illustrates porous layered structure 600 after high temperature processing (e.g., after an epitaxial layer, epilayer 306, is grown over porous layer 304 at high temperatures), according to an exemplary aspect. As shown in FIG. 6, porous layered structure 600 includes porous layer 304 and epilayer 306 with cracks 305 penetrating both layers after high temperature processing. In some aspects, cracks 305 can be created due to stress generated in porous layer 304 during high temperature processing. In some aspects, cracks 305 can be created due to thermal instability in porous layer 304. For example, cracks 305 can be created by migration and/or reorganization of atoms (e.g., silicon, oxygen) in porous layer 304 during high temperature processing.

In some aspects, high temperature processing can include a temperature of at least 400° C. For example, high temperature processing can include a temperature between about 400° C. and about 800° C. In some aspects, high temperature processing can include a temperature of at least 800° C. For example, high temperature processing can include a temperature between about 800° C. and about 1200° C. In some aspects, high temperature processing can include epitaxial processing. For example, epitaxial processing can include growing an epitaxial layer (e.g., epilayer 306) over porous layer 304 at a temperature of at least 400° C.

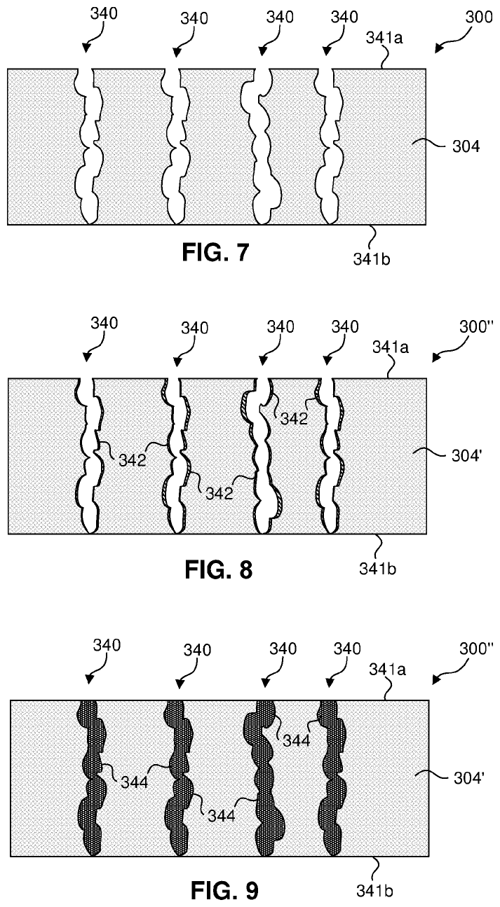

FIG. 7 illustrates porous layer 304 of porous layered structure 300 shown in FIG. 3A, according to an exemplary aspect. As shown in FIG. 7, porous layer 304 has a frontside 341a and a backside 341b and includes pore walls 340. In some aspects, as shown in FIG. 7, pore walls 340 can extend through porous layer 304 from the frontside 341a to the backside 341b. In some aspects, pore walls 340 can be microporous, for example, having a diameter of less than about 2 nm. In some aspects, pore walls 340 can be mesoporous, for example, having a diameter between about 2 nm to about 50 nm. In some aspects, pore walls 340 can be nanoporous, for example, having a diameter of less than about 100 nm. In some aspects, pore walls 340 can be macroporous, for example, having a diameter between about 50 nm to about 1000 nm.

### Exemplary Thermal Layers

As discussed above, when a thick porous layer (e.g., thickness of at least 2 μm) undergoes high temperature processing (e.g., greater than 400° C.), cracking and flaking in the porous layer can occur. For example, as shown in FIG. 6, cracks 305 can form in porous layer 304 which degrades the quality of porous layer 304 and a subsequent epitaxial growth layer (e.g., epilayer 306) on porous layer 304. High temperature processing can induce stress within the porous layer, contributing to these defects. Further, atoms (e.g., silicon) in the porous layer can migrate and reorganize during high temperature processing causing thermal instability in the porous layer, further contributing to these defects.

Aspects of porous layer apparatuses, systems, and methods as discussed below can simultaneously reduce stress within a porous layer, decrease thermal stability of the porous layer, reduce cracking and flaking during high temperature processing of the porous layer, maintain high resistivity of the porous layer (e.g., greater than 5,000 Ω·cm), and increase quality and uniformity of an epitaxial layer grown directly over the porous layer.

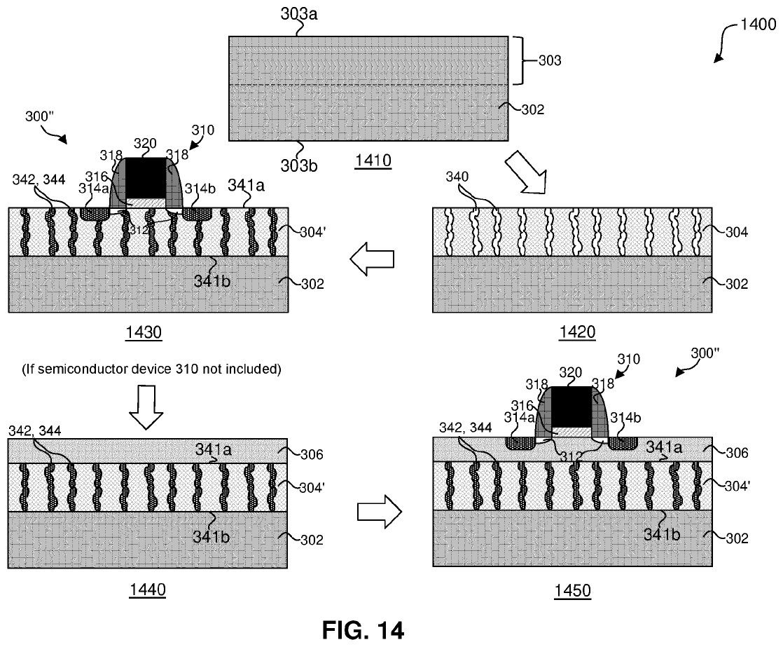

FIG. 8 illustrates porous layer 304′ with thermal layer 342, according to exemplary aspects. Porous layer 304′ can be configured to reduce stress in porous layer 304 and increase thermal stability of porous layer 304. Porous layer 304′ can be further configured to maintain a high resistivity (e.g., greater than 5,000 Ω·cm) of porous layer 304. In some aspects, porous layer 304′ can be utilized in a porous layered structure, for example, porous layered structure 300″ shown in step 1450 of FIG. 14. Although porous layer 304′ is shown in FIG. 8 as a stand-alone apparatus and/or system, aspects of this disclosure can be used with other apparatuses, systems, and/or methods, for example, porous layered structure 300″, manufacturing diagram 1400, and/or flow diagram 1900.

The aspects of porous layer 304 shown in FIG. 7, for example, and the aspects of porous layer 304′ shown in FIG. 8 may be similar. Similar reference numbers are used to indicate features of the aspects of porous layer 304 shown in FIG. 7 and the similar features of the aspects of porous layer 304′ shown in FIG. 8.

As shown in FIG. 8, porous layer 304′ can include thermal layer 342 coupled to pore walls 340. In some aspects, thermal layer 342 can be configured to reduce stress in porous layer 304. In some aspects, thermal layer 342 can be further configured to decrease (e.g., block) migration of atoms in porous layer 304′ thereby increasing a thermal stability of porous layer 304′ at high temperatures. For example, thermal layer 342 can decrease migration of atoms at temperatures greater than about 850° C. Thermal layer 342 can be further configured to maintain a high resistivity (e.g., greater than 5,000 Ω·cm) of porous layer 304 thereby decreasing harmonic losses at radio frequencies in a semiconductor device. For example, similar to porous layer 304, porous layer 304′ can suppress RF field lines 322 from semiconductor device 310 from penetrating (bleeding) into substrate 302, as shown in FIGS. 3A and 3B.

In some aspects, thermal layer 342 can include a thermal oxide. For example, thermal layer 342 can include silicon dioxide. In some aspects, thermal layer 342 can be formed along pore walls 340 within porous layer 304′ by heating porous layer 304 at a heating temperature for a heating time in an oxidizing environment. In some aspects, the ratio (° C./hr) of the heating temperature and the heating time of porous layer 304 can be between a range of about 10° C./hr to about 500° C./hr. In some aspects, the heating temperature can be about 75° C. to about 500° C. In some aspects, the heating temperature can be at least 200° C. In some aspects, the heating temperature can be at least 300° C. In some aspects, the heating time can be about 30 minutes to about 5 hours. In some aspects, the heating time can be no longer than 3 hours. In some aspects, the heating time can be no longer than 1 hour. In some aspects, the oxidizing environment can include air, oxygen, steam, or a combination thereof. In some aspects, heating porous layer 304 to form porous layer 304′ can include annealing porous layer 304.

The heating temperature and heating time (i.e., the ratio (° C./hr)) can be configured to reduce stress in porous layer 304′ such that defects (e.g., cracking, flaking) during high temperature processing can be reduced. Prevention of defects (e.g., cracking, flaking) during high temperature processing (e.g., growing an epitaxial layer over porous layer 304′ at high temperatures) can increase the quality and uniformity of the epitaxial layer (e.g., epilayer 306) grown over porous layer 304′. Further, reduced stress in porous layer 304′ can reduce the dislocation density of epilayer 306, since stress can be reduced at the interface of porous layer 304′ and epilayer 306. For example, in an aspect, the dislocation density of epilayer 306 can be approximately equivalent to that of bulk silicon.

The heating temperature, time, and environment can control the thickness of thermal layer 342. In some aspects, thermal layer 342 can have a thickness less than 5 nm. For example, thermal layer 342 can have a thickness of about 2 nm. In some aspects, thermal layer 342 can have a thickness of at least 5 nm. For example, thermal layer 342 can have a thickness between about 5 nm to about 50 nm. For example, thermal layer 342 can have a thickness of about 20 nm.

As shown in FIG. 8, thermal layer 342 can extend continuously along pore walls 340 from frontside 341a to backside 341b of porous layer 304′. In some aspects, thermal layer 342 can be electrically insulating. For example, thermal layer 342 can include an electrically insulating oxide (e.g., silicon dioxide).

In some aspects, prior to formation of thermal layer 342, pore walls 340 of porous layer 304 can be exposed to an acid solution to remove any native oxide and/or contaminants on pore walls 340. For example, porous layer 304 can undergo an HF dip and subsequently be flushed with deionized (DI) water. In some aspects, prior to formation of thermal layer 342, pore walls 340 can be prepared for passivation. For example, preparing pore walls 340 for passivation (e.g., oxygen passivation caused by heating porous layer 304 in an oxidizing environment) can include hydrogen terminating dangling bonds within pore walls 340. Upon heating in an oxidizing environment, the hydrogen terminations can be displaced and the dangling bonds can be passivated with oxygen atoms.

In some aspects, after formation of thermal layer 342, porous layer 304′ can undergo a touch polish to remove an upper surface layer (e.g., frontside 341a) and expose the underlying porous structure (e.g., pore walls 340) prior to subsequent epitaxial growth. For example, frontside 341a of porous layer 304′ can be polished by a chemical mechanical polishing (CMP) or planarization process. In some aspects, after formation of thermal layer 342, porous layer 304′ can undergo a plasma surface etch to remove an upper surface layer (e.g., frontside 341a) and expose the underlying porous structure (e.g., pore walls 340) prior to subsequent epitaxial growth. For example, frontside 341a of porous layer 304′ can be etched by a plasma etcher.

In some aspects, based on the heating temperature, time, porous layer thickness, and/or environment, the thickness of thermal layer 342 can be increased until the space between pore walls 340 is completely filled. For example, as shown in FIG. 9, porous layer 304′ can include filled thermal layer 344. In some aspects, filled thermal layer 344 can be formed by the process described above with respect to thermal layer 342 shown in FIG. 8. In some aspects, filled thermal layer 344 can have substantially the same properties as thermal layer 342.

### Exemplary IR Transmission Data of Porous Layers

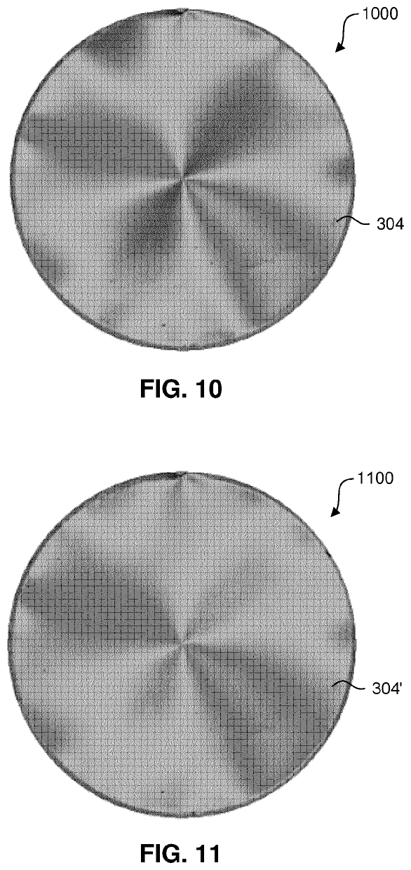

FIGS. 10-13 illustrate and compare infrared (IR) transmission data of porous layers 304 with corresponding porous layers 304′ subsequently formed from porous layers 304, according to exemplary aspects. In some aspects, IR transmission data can be generated by exposing a sample to IR radiation and measuring the IR radiation transmitted through the sample with a detector (e.g., CCD, photodiode, etc.). In some aspects, IR transmission data can be compared to a reference sample (e.g., a 200 mm silicon wafer), for example, having a known reference wafer stress and corresponding IR transmission reference spectra. In some aspects, IR transmission data can be based on polarized IR imaging or polarized stress imaging (PSI) that is based on measurement of IR light depolarization. In some aspects, the variance of the IR transmission data can be proportional to the stress in the sample. In some aspects, variance can be qualitatively (e.g., visually) illustrated by the contrast of dark and light regions of FIGS. 10-13. In some aspects, variance can be quantitatively measured as the square of the standard deviation (σ²) of the IR transmission data. As discussed below, the value of the variance of IR transmission data (e.g., given in terms of relative intensity, unitless), which is proportional to the level of stress of the measured material (e.g., porous layer 304, porous layer 304′), is noted for each IR transmission image.

The variance in the IR transmission data (proportional to the stress) in a porous layer 304 or a porous layer 304′ having undergone heating, can depend upon the following non-exclusive factors:
a. Material. In some aspects, porous layer 304 can comprise silicon. In some aspects, porous layer 304 can comprise any suitable material having a predetermined crystallographic orientation, including but not limited to, germanium, gallium nitride, and other III-V semiconductors.
b. Material thickness. In some aspects, porous layer 304 can have a thickness of at least 2 μm. For example, porous layer 304 can have a thickness between about 2 μm to about 10 μm. In some aspects, porous layer 304 can have a thickness of at least 10 μm. For example, porous layer 304 can have a thickness between about 10 μm to about 50 μm.
c. Material porosity. In some aspects, porous layer 304 can have a porosity of about 20% to 80%. In some aspects, the porosity can vary through the thickness of porous layer 304. For example, porous layer 304 can be porous in one or more sublayers. In some aspects, porous layer 304 can include a first portion (e.g., upper) which is porous and a second portion (e.g., lower) that is non-porous. In some aspects, the porosity of porous layer 304 can be constant or variable. For example, for variable porosity, the porosity can be linearly varied through the thickness, or can be varied according to a different function (e.g., quadratic, logarithmic, step function, etc.). In some aspects, pore walls 340 in porous layer 304 can be microporous (e.g., less than 2 nm pore size), mesoporous (e.g., 2 nm to 50 nm pore size), nanoporous (e.g., less than 100 nm pore size), or macroporous (e.g., 50 nm to 1000 nm pore size).
d. Heating temperature. In some aspects, the heating temperature can be about 75° C. to about 500° C. For example, the heating temperature can be about 300° C. In some aspects, the heating temperature can be at least 200° C. In some aspects, the heating temperature can be at least 300° C.
e. Heating time. In some aspects, the ratio (° C./hr) of the heating temperature and the heating time of porous layer 304 can be between a range of about 10° C./hr to about 500° C./hr. In some aspects, the heating time can be about 30 minutes to about12 hours. For example, the heating time can be about 1 hour. In some aspects, the heating time can be no longer than 3 hours. In some aspects, the heating time can be no longer than 1 hour.
f. Heating environment. In some aspects, the heating environment can be an oxidizing environment. For example, the heating environment can comprise oxygen, steam, or a combination thereof.

In some aspects, for a given porous layer 304 constituting a certain material, thickness, and porosity, stress can decrease upon application of heat over time in an oxidizing environment. In some aspects, a decrease in stress is proportional to a decrease in the variance of IR transmission data, and can be approximated by comparing the variance in IR transmission data of a sample before and after a heating process. In some aspects, the variance of IR transmission data (proportional to the stress) can decrease upon thermal oxidation by greater than 3%. In some aspects, the variance of IR transmission data (proportional to the stress) can decrease by greater than 5%. In some aspects, the variance of IR transmission data (proportional to the stress) can decrease by greater than 10%. In some aspects, the variance of IR transmission data (proportional to the stress) can decrease by greater than 15%. For example, the variance of IR transmission data (proportional to the stress) can decrease by about 3% to about 25%, from about 5% to about 20%, or from about 10% to about 15%.

In some aspects, the variance of IR transmission data (proportional to the stress) of porous layer 304 can decrease by at least 15% after a heating process (e.g., bake for 30 minutes at 100° C. in air). In some aspects, the variance of IR transmission data (proportional to the stress) of porous layer 304 can decrease by at least 50% after a heating process (e.g., bake for 1 hour at 100° C. in air). In some aspects, the variance of IR transmission data (proportional to the stress) of porous layer 304 can decrease by at least 70% after a heating process (e.g., bake for 1 hour at 200° C. in air). In some aspects, the variance of IR transmission data (proportional to the stress) of porous layer 304 can decrease by at least 90% after a heating process (e.g., bake for 1 hour at 300° C. in air).

FIGS. 10 and 11 illustrate an exemplary decrease in stress in a porous layer 304 caused by heating porous layer 304 in an oxidizing environment.

FIG. 10 illustrates IR transmission data 1000 of a porous layer 304 prior to thermal oxidation of pore walls 340 to form thermal layer 342, according to an exemplary aspect. For porous layer 304 shown in FIG. 10, the variance of IR transmission data (proportional to the stress) is about 436 (arbitrary units).

FIG. 11 illustrates IR transmission data 1100 of a porous layer 304′ after thermal oxidation of pore walls 340 to form thermal layer 342, according to an exemplary aspect. To form porous layer 304′ shown in FIG. 11, thermal layer 342 was formed on pore walls 340 by heating porous layer 304 of FIG. 10 at a temperature of about 200° C. for a time of about 1 hour in an oxidizing environment (e.g., air). For porous layer 304′ shown in FIG. 11, the variance of IR transmission data (proportional to the stress) is about 361 (arbitrary units), a reduction of about 17.2% (436 to 361) as compared to the variance of IR transmission data of porous layer 304 of FIG. 10.

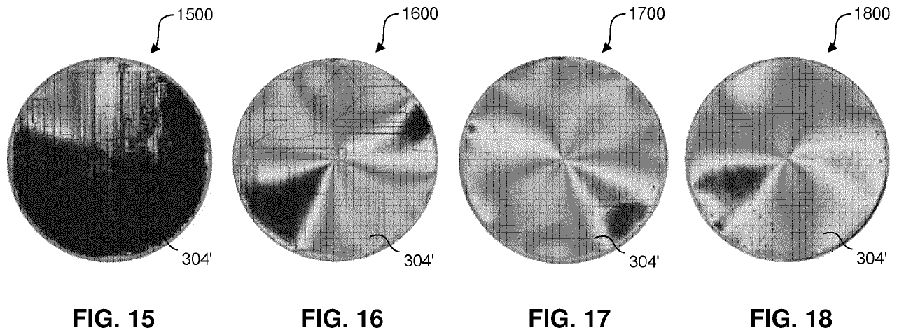

FIGS. 10 and 11 illustrate that forming thermal layer 342 on pore walls 340 by thermal oxidation can reduce the variance of IR transmission data (proportional to the stress) in porous layer 304 prior to growing epilayer 306 or a semiconductor device 310 over porous layer 304′. As shown below with respect to FIGS. 15-18, the reduction in variance of IR transmission data (proportional to the stress) caused by thermal layers 342, 344 in pore walls 340 prior to epitaxy can produce even larger reductions in variance of IR transmission data (proportional to the stress), for example, a reduction of about 98.6% (52,750 to 762)—as compared to a porous layer 304 that did not undergo heating to form thermal layer 342—in porous layered structure 300″ post-epitaxy, with epilayer 306 atop porous layer 304′, thereby increasing uniformity and decreasing defects in epilayer 306.

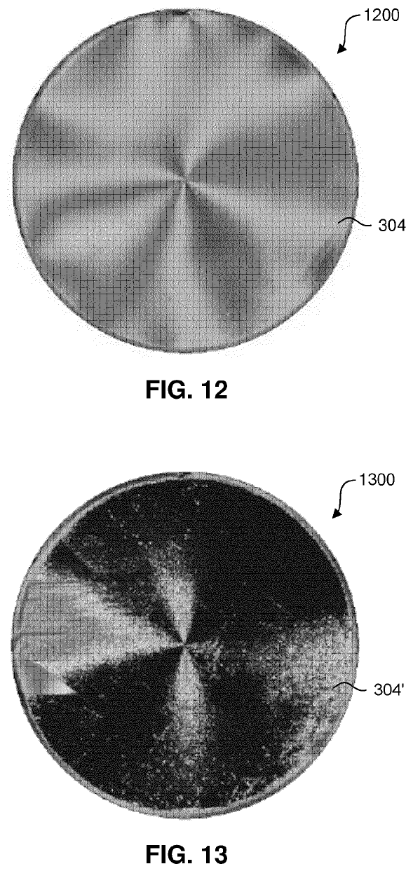

FIGS. 12 and 13 illustrate an exemplary increase in stress in a porous layer 304 caused by heating porous layer 304 in a non-oxidizing environment.

FIG. 12 illustrates IR transmission data 1200 of a porous layer 304 prior to the thermal oxidation of pore walls 340 to form thermal layer 342, according to an exemplary aspect. For porous layer 304 shown in FIG. 12, the variance of IR transmission data (proportional to the stress) is about 472 (arbitrary units).

FIG. 13 illustrates IR transmission data 1300 of a porous layer 304′ after heating porous layer 304. However, to form porous layer 304′ shown in FIG. 13, porous layer 304 shown in FIG. 12 was heated at a temperature of about 300° C. for a time of about 1 hour in a non-oxidizing environment (e.g., nitrogen (N₂)), rather than in an oxidizing environment (e.g. air). For porous layer 304′ shown in FIG. 13, the variance of IR transmission data (proportional to the stress) is about 1745 (arbitrary units), indicating increased variance of IR transmission data (e.g., about 270% increase) as compared to porous layer 304 of FIG. 12. FIGS. 12 and 13 demonstrate that heating porous layer 304 in an oxidizing environment can lead to decreased variance of IR transmission data of porous layer 304′, and thereby decreased stress in porous layer 304′, while heating porous layer 304 in a non-oxidizing environment can lead to increased stress in porous layer 304′.

The present disclosure can therefore provide a method of producing thick porous layers that are stable during subsequent high temperature thermal processing steps. While the present disclosure discusses high-temperature epitaxial growth, it should be understood that the benefits of decreased stress and increased thermal stability in porous layer 304′ can extend to any subsequent processing steps conducted at high temperatures.

### Exemplary Manufacturing Diagram

FIG. 14 illustrates manufacturing diagram 1400 for forming porous layered structure 300″, differentiated from porous layered structure 300 of FIG. 3A by the inclusion of thermal layer 342 within porous layer 304′, according to an exemplary aspect. Porous layer 300″ can include an epilayer 306 (as shown in step 1450) or be formed without epilayer 306 (as shown in step 1430). Porous layered structure 300″ can be configured to suppress harmonic losses in semiconductor device 310, reduce crosstalk, and reduce parasitic surface conduction effects. Although porous layered structure 300″ is shown in step 1450 of FIG. 14 as a stand-alone apparatus and/or system, aspects of this disclosure can be used with other apparatuses, systems, and/or methods, for example, flow diagram 1900.

The aspects of porous layered structures 300 and 300′ shown in FIGS. 3A and 3B, for example, and the aspects of porous layered structure 300″ shown in FIG. 14 may be similar. Similar reference numbers are used to indicate features of the aspects of porous layered structures 300 and 300′ shown in FIGS. 3A and 3B and the similar features of the aspects of porous layered structure 300″ shown in FIG. 14.

As shown in FIG. 14, porous layered structure 300″ can include porous layer 304′ with thermal layer 342. In some aspects, porous layer 304′ can have a high resistivity (e.g., greater than about 5,000 Ω·cm) thereby decreasing harmonic losses in a semiconductor device. In some aspects, porous layer 304′ can have a resistivity equal to or greater than a resistivity of porous layer 304. For example, similarly to porous layer 304, porous layer 304′ can suppress RF field lines 322 from semiconductor device 310 from penetrating (bleeding) into substrate 302, as shown for porous layer 304 in FIGS. 3A and 3B.

It is to be appreciated that not all steps in FIG. 14 are needed to perform the disclosure provided herein. Further, some of the steps can be performed simultaneously, sequentially, and/or in a different order than shown in FIG. 14. Manufacturing diagram 1400 shall be described with reference to FIGS. 7-13. However, manufacturing diagram 1400 is not limited to those example aspects.

As shown in FIG. 14, manufacturing diagram 1400 is configured to form porous layered structure 300″. In step 1410, a substrate 302 having a frontside 303a and a backside 303b is selected. In some aspects, substrate 302 can include any suitable substrate having a predetermined crystallographic orientation, including but not limited to silicon, germanium, and III-V semiconductors.

In step 1420, a portion 303 of substrate 302 is porosified from frontside 303a towards backside 303b to form porous layer 304 with pore walls 340. In some aspects, manufacturing diagram 1400 can further include exposing pore walls 340 of porous layer 304 to an acid solution (e.g., HF) after step 1420 but prior to step 1430. In some aspects, manufacturing diagram 1400 can further include preparing pore walls 340 for passivation after step 1420 but prior to step 1430. For example, preparing pore walls 340 for passivation (e.g., oxygen passivation caused by heating porous layer 304 in an oxidizing environment) can include hydrogen terminating dangling bonds within pore walls 340. In some aspects, upon heating in an oxidizing environment, the hydrogen terminations can be displaced and the dangling bonds can be passivated with oxygen atoms.

In step 1430, porous layer 304′ is formed by forming thermal layer 342 on pore walls 340 of porous layer 304. In some aspects, for example, as described with respect to FIGS. 8-9, porous layer 304′ can be formed by thermally oxidizing porous layer 304 to form thermal layer 342 on pore walls 340. In some aspects, thermally oxidizing porous layer 304 can include heating porous layer 304 at a heating temperature for a heating time in an oxidizing environment. In some aspects, the ratio (° C./hr) of the heating temperature and the heating time of the porous layer 304 can be between a range of about 10° C./hr to about 500° C./hr. In some aspects, the heating temperature can be about 75° C. to about 500°C. In some aspects, the heating temperature can be at least 200° C. In some aspects, the heating temperature can be at least 300° C. In some aspects, the heating time can be about 30 minutes to about 5 hours. In some aspects, the heating time can be no longer than 3 hours. In some aspects, the heating time can be no longer than 1 hour. In some aspects, the oxidizing environment can include air, oxygen, steam, or a combination thereof. In some aspects, heating porous layer 304 to form porous layer 304′ can include annealing porous layer 304.

The heating temperature and heating time (i.e., the ratio or the range of the ratio) can be configured to reduce stress in porous layer 304′ such that cracking during high temperature processing can be reduced. Preventing cracking during high temperature processing (e.g., forming a semiconductor device or growing an epitaxial layer over porous layer 304′ at high temperatures) can increase the quality of the semiconductor device or epitaxial layer (e.g., epilayer 306) grown over porous layer 304′. Further, reduced stress in porous layer 304′ can reduce the dislocation density of epilayer 306, since stress can be reduced at the interface of porous layer 304′ and epilayer 306. For example, in an aspect, the dislocation density of epilayer 306 can be approximately equivalent to that of bulk silicon.

The heating temperature, time, and environment can control the thickness of thermal layer 342. In some aspects, thermal layer 342 can have a thickness less than 5 nm. For example, thermal layer 342 can have a thickness of about 2 nm. In some aspects, thermal layer 342 can have a thickness of at least 5 nm. For example, thermal layer 342 can have a thickness of about 5 nm to about 50 nm. For example, thermal layer 342 can have a thickness of about 20 nm. In some aspects, the thickness of thermal layer 342 can be increased until the space between pore walls 340 is completely filled, as shown in FIG. 9.

In some aspects, step 1430 can include forming a semiconductor device 310 in porous layer 304′. For example, as shown in FIG. 14, porous layered structure 300″ can include porous layer 304′ with semiconductor device 310 and omit epilayer 306. In some aspects, semiconductor device 310 can be a transistor (e.g., MOSFET) in a CMOS device. In some aspects, semiconductor device 310 in or on porous layer 304′ can include an RF device (e.g., an RF inductor, an RF filter, etc.). For example, the RF device can include RF switch 412 shown in FIG. 4).

In some aspects, porous layer 304′ can undergo a touch polish in step 1430 to remove an upper surface layer (e.g., frontside 341a) and expose the underlying porous structure (e.g., pore walls 340) prior to subsequent semiconductor device formation or epitaxial growth. For example, frontside 341a of porous layer 304′ can be polished by a CMP or planarization process. In some aspects, porous layer 304′ can undergo a plasma surface etch to remove an upper surface layer (e.g., frontside 341a) and expose the underlying porous structure (e.g., pore walls 340) prior to subsequent semiconductor device formation or epitaxial growth. For example, frontside 341a of porous layer 304′ can be etched by a plasma etcher.

If semiconductor device 310 is not formed in porous layer 304′, in step 1440, an epilayer 306 is grown over porous layer 304′ (e.g., on frontside 341a). In some aspects, epilayer 306 can include any suitable epilayer having a predetermined crystallographic orientation, including but not limited to silicon, germanium, and III-V semiconductors. In some aspects, epilayer 306 can be a defect-free, single crystal epilayer formed directly atop porous layer 304′.

In step 1450, a semiconductor device 310 can be formed in epilayer 306 to form porous layered structure 300″. In some aspects, semiconductor device 310 can be a transistor (e.g., MOSFET) in a CMOS device. In some aspects, semiconductor device 310 can include an RF device (e.g., an RF inductor, an RF filter, etc.). For example, the RF device can include RF switch 412 shown in FIG. 4. In some aspects, porous layered structure 300″ can omit semiconductor device 310 in epilayer 306, for example, as shown in step 1440 of FIG. 14. In some aspects, porous layered structure 300″ can omit epilayer 306 over porous layer 304′, for example, as shown in step 1430 of FIG. 14.

### Exemplary IR Transmission Data of Porous Layered Structures

FIGS. 15-18 illustrate and compare infrared (IR) transmission data 1500, 1600, 1700, 1800 of various porous layers 304′ with epitaxial layers (e.g., epilayer 306) (e.g., after step 1440 of FIG. 14), according to exemplary aspects. While the below comparison discusses porous layers 304′ having undergone subsequent epitaxial growth at high temperatures, it should be understood that the effects discussed below extend to porous layers 304′ having undergone any type of high-temperature processing.

IR transmission data 1500, 1600, 1700, 1800 shown in FIGS. 15-18 is similar to IR transmission data 1100 shown in FIG. 11 with the addition of epilayer 306 over porous layer 304′ (e.g., porous layered structure 300″). The aspects of porous layer 304′ shown in FIG. 11, for example, and the aspects of porous layers 304′ shown in FIGS. 15-18 may be similar. Similar reference numbers are used to indicate features of the aspects of porous layer 304′ shown in FIG. 7 and the similar features of the aspects of porous layers 304′ shown in FIGS. 15-18.

In some aspects, a wavelength (λ) of the IR radiation can be about 1 micron to about 5 microns. For example, the wavelength (λ) can be about 1.3 microns. In some aspects, the thickness of epilayer 306 can be less than the thickness of porous layer 304′. For example, the thickness of epilayer 306 can be no greater than about 1 micron. In some aspects, the thickness of epilayer 306 can be no greater than about 25% the thickness of porous layer 304′. In some aspects, epilayer 306 can include an IR transmissive material. For example, epilayer 306 can include crystalline silicon. In some aspects, a wavelength of the IR radiation, a thickness of epilayer 306, and a transmissivity of epilayer 306 can ensure IR transmission data from IR radiation transmitted through both porous layer 304′ and epilayer 306 is proportional to the stress in porous layer 304′. For example, IR transmission data is proportional to the stress in porous layer 304′ based on a weighting factor (e.g., based on a reference sample).

As discussed above with respect to FIGS. 10-13, the variance in IR transmission data is proportional to the stress in a material (e.g., porous layer 304′) or a layered structure (e.g., porous layered structure 300″). In some aspects, variance can be qualitatively (e.g., visually) illustrated by the contrast of dark and light regions of FIGS. 15-18. In some aspects, variance can be quantitatively measured as the square of the standard deviation (σ²) of the IR transmission data. As discussed below, the value of the variance of IR transmission data (arbitrary units), which is proportional to the level of stress of the measured material (e.g., porous layer 304′, porous layered structure 300″), is noted for each IR transmission image. In some aspects, cracks (visible as lines) in porous layers 304′ can be seen, for example, in FIGS. 15-17.

As discussed above with respect to FIGS. 10-13, the stress in a porous layer 304′ having undergone a heating process, and therefore the variance in IR transmission data (proportional to the stress), can depend upon several parameters, including material, material thickness, material porosity, heating temperature, heating time, and heating environment. Further, these parameters can be modified as described with respect to FIGS. 10-13, causing a decrease in stress in porous layer 304′ as compared to porous layer 304 of similar material, thickness, and porosity that did not undergo the heating process (e.g., thermal oxidation to generate thermal layer 342). In some aspects, the decrease in the variance of IR transmission data (proportional to the stress) can be measured by comparing the variance in IR transmission data of a sample having undergone heating prior to epitaxy to the variance in IR transmission data of a sample having undergone minimal or no heating prior to epitaxy.

In some aspects, the variance of IR transmission data (proportional to the stress) of a porous layer 304′ upon which epilayer 306 has been grown can decrease (as compared with a similar porous layer 304 that underwent minimal or no thermal oxidation prior to epitaxy), for example, by greater than 25%. In some aspects, the variance of IR transmission data (proportional to the stress) can decrease by greater than 50%. In some aspects, the variance of IR transmission data (proportional to the stress) can decrease by greater than 60%. In some aspects, the variance of IR transmission data (proportional to the stress) can decrease by greater than 70%. In some aspects, the variance of IR transmission data (proportional to the stress) can decrease by greater than 80%. In some aspects, the variance of IR transmission data (proportional to the stress) can decrease by greater than 90%. In some aspects, the variance of IR transmission data (proportional to the stress) can decrease by greater than 95%. For example, the variance of IR transmission data (proportional to the stress) can decrease by about 25% to about 99%, about 50% to about 99%, about 60% to about 99%, about 70% to about 99%, about 80% to about 99%, or about 90% to about 99%.

FIGS. 15-18 illustrate exemplary decreases in stress in porous layers 304′ post epitaxy caused by heating porous layers 304 in an oxidizing environment prior to epitaxy.

For each of the porous layers 304′ shown in FIGS. 15-18, the material, material thickness, material porosity, and heating environment were substantially the same. Further, growing epilayer 306 over each of porous layers 304′ involved substantially similar epitaxy processes. For example, the temperature at which epilayer 306 was grown and time duration of the growth of epilayer 306 did not vary substantially among porous layers 304′ shown in FIGS. 15-18. Further, the material of epilayer 306 did not substantially vary among porous layers 304′ shown in FIGS. 15-18.

FIG. 15 illustrates IR transmission data 1500 of a porous layer 304′ after growing an epitaxial layer (e.g., epilayer 306) over porous layer 304′. To form porous layer 304′ shown in FIG. 15, prior to epitaxial growth, porous layer 304 was heated at a temperature of about 90° C. for a time of about 10 minutes in an oxidizing environment (e.g., air), resulting in either a nonexistent or very thin thermal layer 342. For the porous layer 304′ shown in FIG. 15, the variance of IR transmission data (proportional to the stress) is about 52,750 (arbitrary units), indicating high levels of stress in porous layer 304′). Further, as shown in FIG. 15, a number of cracks can be seen. The high levels of stress within the porous layer 304′ shown in FIG. 15 can be attributed to the low temperature and short time of the heating of porous layer 304′, resulting in a very thin, if any, thermal layer 342 in porous layer 304′ prior to epitaxy.

FIG. 16 illustrates IR transmission data 1600 of a porous layer 304′ after growing an epitaxial layer (e.g., epilayer 306) over porous layer 304′. To form porous layer 304′ shown in FIG. 16, prior to epitaxial growth, thermal layer 342 was formed on pore walls 340 by heating a porous layer 304 at a temperature of about 90° C. for a time of about 5 hours in an oxidizing environment (e.g., air). For porous layer 304′ shown in FIG. 16, the variance of IR transmission data (proportional to the stress) is about 3,012 (arbitrary units), a reduction of about 94.3% (52,750 to 3,012) as compared to porous layer 304′ shown in FIG. 15. Further, a reduced number of cracks can be seen in porous layer 304′ shown in FIG. 16, corresponding to a reduced number of cracks within epilayer 306. The reduced levels of stress within porous layer 304′ shown in FIG. 16 can be attributed to the lengthened time of the heating of porous layer 304, resulting in a thicker thermal layer 342.

FIG. 17 illustrates IR transmission data 1700 of a porous layer 304′ after growing an epitaxial layer (e.g., epilayer 306) over porous layer 304′. To form porous layer 304′ shown in FIG. 17, prior to epitaxial growth, thermal layer 342 was formed on pore walls 340 by heating a porous layer 304 at a temperature of about 200° C. for a time of about 1 hour in an oxidizing environment (e.g., air). For porous layer 304′ shown in FIG. 17, the variance of IR transmission data (proportional to the stress) is about 850 (unitless), a reduction of about 98.4% (52,750 to 850) as compared to porous layer 304′ shown in FIG. 15. Further, a reduced number of cracks can be seen in porous layer 304′ shown in FIG. 17, corresponding to a reduced number of cracks within epilayer 306. The reduced levels of stress in porous layer 304′ shown in FIG. 17 can be attributed to the increased temperature of the heating of porous layer 304, resulting in a thicker thermal layer 342. Although the heating time has been shortened, the increased temperature compared to the relatively low-temperature examples of FIGS. 15-16 can produce greater levels of thermal oxidation on pore walls 340.

Porous layer 304′ shown in FIG. 17 is porous layer 304′ shown in FIG. 11. While growth of epilayer 306 has produced an increase in the variance of IR transmission data as compared to porous layer 304′ shown in FIG. 11 prior to epitaxy, the increase is substantially smaller than the increase for a porous layer that underwent minimal or no thermal oxidation prior to epitaxy. For example, the increase in the variance of IR transmission data (proportional to the stress) of porous layer 304′ shown in FIG. 15 during the epitaxial growth process is about 12,098.6%, considering porous layer 304′ shown in FIG. 15 to be similar to porous layer 304 shown in FIG. 10.

FIG. 18 illustrates IR transmission data 1800 of a porous layer 304′ after growing an epitaxial layer (e.g., epilayer 306) over porous layer 304′. To form porous layer 304′ shown in FIG. 18, prior to epitaxial growth, thermal layer 342 was formed on pore walls 340 by heating a porous layer 304 at a temperature of about 300° C. for a time of about 1 hour in an oxidizing environment (e.g., air). For porous layer 304′ shown in FIG. 18, the variance of IR transmission data (proportional to the stress) is about 762 (arbitrary units), a reduction of about 98.6% (52,750 to 762) as compared to porous layer 304′ shown in FIG. 15. Further, no visible cracks can be seen in porous layer 304′ shown in FIG. 18, corresponding to a reduced number of cracks within epilayer 306. The reduced levels of stress in porous layer 304′ shown in FIG. 18 can be attributed to the increased temperature of the heating of porous layer 304, resulting in a thicker thermal layer 342.

In some aspects, the decrease in stress in porous layer 304′ can depend upon the thickness of thermal layer 342. In some aspects, stress in porous layer 304′ can decrease as the thickness of thermal layer 342′ increases. In some aspects, the decrease in stress in porous layer 304′ as the thickness of thermal layer 342 increases can reach a limit. For example, with continued heating in an oxidizing environment, filled thermal layer 344 can exert pressure on pore walls 340, leading to an increase in stress. In some aspects, the decrease in stress in porous layer 304′ can depend upon a temperature and a time of an oxidation bake. For example, for an oxidation back at about 300° C. for a time of about 1 hour, the stress in porous layer 304′ (e.g., porous silicon) is approximately equivalent to that of bulk silicon (e.g., based on X-ray diffraction (XRD) data).

In some aspects, controlling the temperature and the time of the heating of porous layer 304 (and thereby controlling the thickness of thermal layer 342) can provide a method of fine-tuning the stress in porous layer 304′. The ability to fine-tune stress in porous layer 304′ can correspond to an ability to maximally reduce stress in porous layer 304′ to decrease cracking caused by stress in porous layer 304′ during high-temperature processing. As cracks in porous layer 304′ induced during high temperature processing can correspond to cracks within an epitaxial layer (e.g., epilayer 306) grown over porous layer 304′ at high temperatures, the present disclosure can provide a method of producing higher-quality epitaxial growth over a porous layer. Further, reducing stress in porous layer 304′ can reduce dislocation defects within epilayer 306 caused by stress at the interface of epilayer 306 and porous layer 304′.

### Exemplary Flow Diagram

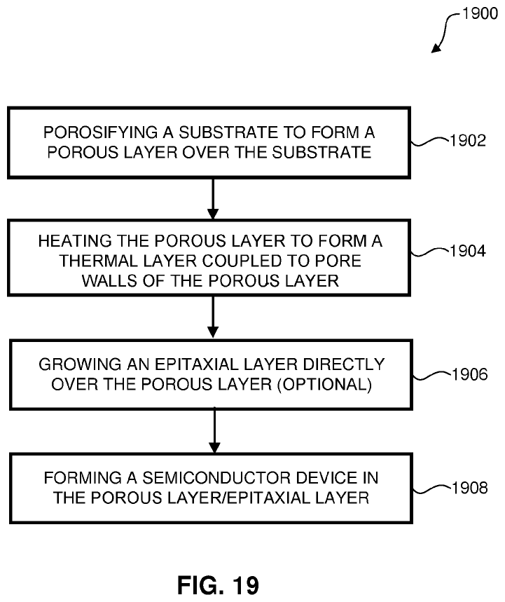

FIG. 19 illustrates flow diagram 1900 to describe the process of forming porous layered structure 300″, according to an exemplary aspect. It is to be appreciated that not all steps in FIG. 19 are needed to perform the disclosure provided herein. Further, some of the steps can be performed simultaneously, sequentially, and/or in a different order than shown in FIG. 19. Flow diagram 1900 shall be described with reference to FIGS. 7-18. However, flow diagram 1900 is not limited to those example aspects.

As shown in FIG. 19, flow diagram 1900 describes the process to form porous layered structure 300″ shown in FIG. 14. In step 1902, as shown in the example of FIG. 14, a portion 303 of substrate 302 is porosified from frontside 303a towards backside 303b to form porous layer 304 with pore walls 340. In some aspects, flow diagram 1900 can further include exposing pore walls 340 of porous layer 304 to an acid solution (e.g., HF) after porosifying substrate 302 to form porous layer 304. In some aspects, flow diagram 1900 can further include preparing pore walls 340 for passivation after porosifying substrate 302 to form porous layer 304. For example, preparing pore walls 340 for passivation (e.g., oxygen passivation caused by heating porous layer 304 in an oxidizing environment) can include hydrogen terminating dangling bonds within pore walls 340. Upon heating in an oxidizing environment, the hydrogen terminations can be displaced and the dangling bonds can be passivated with oxygen atoms.

In step 1904, as shown in the example of FIG. 14, porous layer 304′ is formed by forming thermal layer 342 coupled to pore walls 340 of porous layer 304. In step 1906, an epilayer 306 is optionally grown over porous layer 304′ (e.g., on frontside 341a). In step 1908, as shown in the example of FIG. 14, a semiconductor device 310 is formed in either porous layer 304′ or epilayer 306 to form porous layered structure 300″.

In some aspects, after step 1904 but prior to step 1906 or step 1908, porous layer 304′ can undergo a touch polish to remove an upper surface layer (e.g., frontside 341a) and expose the underlying porous structure (e.g., pore walls 340) prior to semiconductor device formation or subsequent epitaxial growth. For example, frontside 341a of porous layer 304′ can be polished by a CMP or planarization process. In some aspects, after step 1904 but prior to step 1906 or step 1908, porous layer 304′ can undergo a plasma surface etch to remove an upper surface layer (e.g., frontside 341a) and expose the underlying porous structure (e.g., pore walls 340) prior to semiconductor device formation or subsequent epitaxial growth. For example, frontside 341a of porous layer 304′ can be etched by a plasma etcher.

It is to be understood that the phraseology or terminology herein is for the purpose of description and not of limitation, such that the terminology or phraseology of the present specification is to be interpreted by those skilled in relevant art(s) in light of the teachings herein.

The following examples are illustrative, but not limiting, of the aspects of this disclosure. Other suitable modifications and adaptations of the variety of conditions and parameters normally encountered in the field, and which would be apparent to those skilled in the relevant art(s), are within the spirit and scope of the disclosure.

While specific aspects have been described above, it will be appreciated that the aspects can be practiced otherwise than as described. The description is not intended to limit the scope of the claims.

The aspects have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects will so fully reveal the general nature of the aspects that others can, by applying knowledge within the skill of the art, readily modify and/or adapt for various applications such specific aspects, without undue experimentation, without departing from the general concept of the aspects. Therefore, such adaptations and modifications are intended to be within the meaning and range of equivalents of the disclosed aspects, based on the teaching and guidance presented herein.

The breadth and scope of the aspects should not be limited by any of the above-described exemplary aspects, but should be defined only in accordance with the following claims and their equivalents.

1. A layered structure comprising:
a porous layer over a substrate, the porous layer having a higher resistivity than the substrate, a variance of infrared (IR) transmission data of the porous layer being no greater than 2,500; and
a thermal oxide layer coupled to pore walls of the porous layer.

2. The layered structure of claim 1, further comprising an epitaxial layer grown directly over the porous layer.

3. The layered structure of claim 1, wherein the variance of IR transmission data is no greater than 1,000 or no greater than 500.

4. The layered structure of claim 2, wherein a dislocation density of the epitaxial layer is approximately equivalent to that of bulk silicon.

5. The layered structure of claim 1, wherein the porous layer has a thickness of at least 2 μm.

6. The layered structure of claim 1, wherein the thermal oxide layer is configured to decrease migration of atoms in the porous layer thereby increasing thermal stability of the porous layer at temperatures greater than about 850° C.

7. The layered structure of claim 1, wherein the thermal oxide layer extends continuously along the pore walls from a frontside of the porous layer to a backside of the porous layer.

8. The layered structure of claim 1, wherein the thermal oxide layer at least partially fills the space between the pore walls.

9. The layered structure of claim 1, wherein the thermal oxide layer comprises silicon dioxide (SiO₂).

10. The layered structure of claim 1, further comprising a semiconductor device in the porous layer or in the epitaxial layer.

11. The layered structure of claim 10, wherein the semiconductor device comprises a radio frequency (RF) device.

12. A method of manufacturing a layered structure, the method comprising:
forming a porous layer over a substrate; and
heating the porous layer in an oxidizing environment to form a thermal oxide layer coupled to pore walls of the porous layer,
wherein a ratio (° C./hr) of a heating temperature and a heating time of the porous layer is between a range of 10° C./hr to 500° C./hr.

13. The method of claim 12, further comprising growing an epitaxial layer or forming a semiconductor device directly over the porous layer,
wherein growing the epitaxial layer or forming the semiconductor device is after heating the porous layer.

14. The method of claim 12, wherein the heating temperature is 75° C. to 500° C.

15. The method of claim 12, wherein the heating time is 30 minutes to 12 hours.

16. The method of claim 12, wherein the oxidizing environment comprises air, oxygen, steam, or a combination thereof.

17. The method of claim 12, further comprising preparing the pore walls of the porous layer for passivation prior to heating the porous layer,
wherein preparing the pore walls of the porous layer for passivation comprises hydrogen terminating dangling bonds within the pore walls.

18. The method of claim 12, wherein heating the porous layer comprises annealing the porous layer.
